(19) United States
(12) Patent Application Publication
(10) Pub. No.: US 2004/0004225 A1
(43) Pub. Date: Jan. 8, 2004

(54) Light emitting diode and manufacturing method thereof

(75) Inventors: Ying-Che Sung, Taipei (TW); Chi-Wei Lu, Taipei (TW); Wen-Chieh Huang, Taipei (TW)

Correspondence Address: QUINTERO LAW OFFICE, 1617 BROADWAY, 3RD FLOOR, SANTA MONICA, CA, 90404, US

(73) Assignee: Arima Optoelectronics Corp.

(21) Appl. No.: 10/289,885

(22) Filed: Nov. 7, 2002

(30) Foreign Application Priority Data
Jul. 8, 2002 (TW) 91115061

(51) Int. Cl. H01L 33/00

(52) U.S. Cl. 257/90

(57) ABSTRACT

A light emitting diode and manufacturing method thereof. The light emitting diode comprises a n-type semiconductor layer formed on a substrate, an active layer formed on the n-type semiconductor layer, a p-type cladding layer formed on the active layer, and a hydrogen-adsorbing layer formed on the p-type cladding layer. The hydrogen-adsorbing layer adsorbs the hydrogen atoms near the interface to the p-type cladding layer, thereby enhancing the doping concentration of p-type cladding layer, and forming a low-resist ohmic contact by which the performance and reliability of opto-electronic devices is improved.

### BACKGROUND OF THE INVENTION

1. Field of the Invention

The present invention relates to the field of light emitting diodes. More particularly, the invention relates to ohmic contact on a p-type cladding layer and the method for manufacturing thereof.

2. Description of the Related Art

FIG. 1 shows a III-V group semiconductor light emitting device. The light emitting device 1 comprises a transparent and electrically insulated substrate 2, for example, a sapphire substrate. A III-V group semiconductor layer 3 based on n-type GaN is formed on the first surface 2a of the substrate 2. A III-V group cladding layer 4 based on p-type GaN is then formed on the n-type semiconductor layer 3. Part of the p-type cladding layer 4 is removed after to expose the surface of the n-type semiconductor layer 3. n-electrode pad 5 and p-electrode film 6 are then formed on the n-type semiconductor layer 3 and the p-type cladding layer 4 respectively, and a p-electrode pad 20 is then formed on the p-electrode film 6.

In the III-V group semiconductor light emitting device manufacturing process, the V group elements are usually dissociated from hydride gas, such as NH3, PH3, and AsH3, thus some hydrogen atoms are kept inside the III-V group semiconductor after the dissociation. The III-V group semiconductor is then doped with dopants such as Mg to form a p-type cladding layer, but Mg easily forms a complex with hydrogen atoms and thus lowers the effective carrier concentration unless an annealing step is performed to help achieve a high p-type doping level. To recover the electrical activity of Mg, the annealing temperature must be higher than 400° C., thus the cost is raised. If an annealing step is not performed, the carrier concentration of p-type cladding layer doped with Mg is restricted, for example, the doping concentration of GaN is restricted under 1018 cm−3 after metal organic chemical vapor deposition of Mg. Low carrier concentration results in high parasitic resistance of contact electrode, reducing performance of semiconductor devices.

### SUMMARY OF THE INVENTION

Thus, the purpose of the invention is to address the high-resistance issue and lower the contact resistance to achieve better performance.

To achieve the purpose, the invention provides a light emitting diode whereby hydrogen-adsorbing materials are used to break bonding of Mg-H complex by their strong hydrogen adsorbing ability, so carrier concentration of p-type cladding layer is raised, the interfacial resistance of ohmic contact is lowered, and the performance and reliability of the light emitting diode are thus enhanced.

The manufacturing method provided comprises providing a substrate, forming a n-type semiconductor layer on the substrate, forming an active layer on the n-type semiconductor layer, forming a p-type cladding layer on the active layer, and forming a hydrogen-adsorbing layer on the p-type cladding layer. In the p-type cladding layer, hydrogen atoms near the interface between the p-type cladding layer and the hydrogen-adsorbing layer are adsorbed because of the strong hydrogen-adsorbing ability of the hydrogen-adsorbing material, thus the carrier concentration in p-type cladding layer is increased, and a low-resistance ohmic contact is formed.

### BRIEF DESCRIPTION OF THE DRAWINGS

The following detailed description, given by way of example and not intended to limit the invention solely to the embodiments described herein, will best be understood in conjunction with the accompanying drawings, in which:

FIG. 1 shows a III-V group semiconductor light emitting device;

FIG. 2 shows the light emitting diode of the first embodiment in the present invention; and

FIG. 3 shows the light emitting diode of the second embodiment in the present invention.

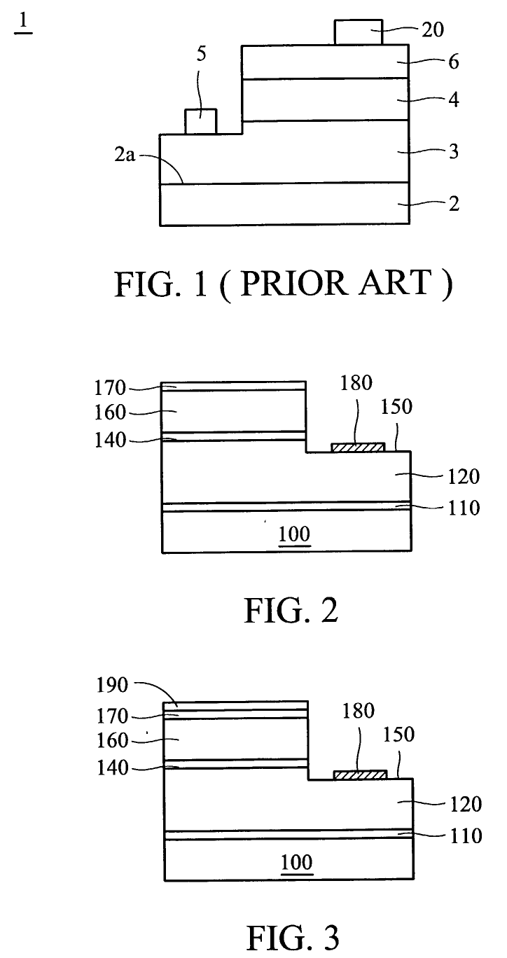

### DETAILED DESCRIPTION OF THE INVENTION

First Embodiment

FIG. 2 shows the light emitting diode of the first embodiment in the present invention. As in FIG. 2, the light emitting diode comprises a substrate 100, a n-type semiconductor layer 120 formed on the substrate 100, an active layer 140 formed on the n-type semiconductor layer 120 and exposes part of the surface 150 of the n-type semiconductor layer 120, a p-type cladding layer 160 formed on the active layer 140, a n-type contact electrode 180 formed on the exposed surface 150 of n-type semiconductor layer 120, and a hydrogen-adsorbing layer 170 formed on the p-type cladding layer 160.

First, a substrate 100 of, for example, sapphire is provided. The material of substrate 100 can also be spinnel, SiC, or GaAs. A buffer layer 110 of AlN, GaN, or AlGaN can be formed selectively on the substrate 100.

Second, a n-type GaN epitaxial layer 120 is formed on the buffer layer 110 by molecular beam epitaxy (MBE) or metal-organic chemical vapor deposition (MOCVD).

An active layer 140 is formed on the n-type GaN epitaxial layer 120. The active layer 140 is, for example, Indium compound (such as InGaN) or AlGaAs used in double hetero-structure LED, and other dopants such as Tl, or compounds such as CdSi, CdTe, ZnSi, ZnTe can be also added in to adjust the band gap of the active layer 140 and switch the wavelength of emitted light.

A p-type GaN epitaxial layer 160 is formed by MBE or MOCVD process. The active layer 140 and the p-type GaN epitaxial payer 160 are then patterned by etching to expose the part of the surface 150 of the n-type GaN epitaxial layer 120. Then a hydrogen-adsorbing layer 170 is deposited on the surface of the p-type GaN epitaxial layer 160 by, for example, evaporation. A n-type contact electrode 180 is then formed on the surface 150. The material of the hydrogen-adsorbing layer 170 is Ta, V, Zr, Th, Ti, Pd, PdAg, Mg2Ni, NiTi, FeTi or LaNi5.

Second Embodiment.

FIG. 3 shows the light emitting diode of the second embodiment in the present invention. As in FIG. 3, the light emitting diode comprises a substrate 100, a n-type semiconductor layer 120 formed on the substrate 100, an active layer 140 formed on the n-type semiconductor layer 120 and exposes part of the surface 150 of the n-type semiconductor layer 120, a p-type cladding layer 160 formed on the active layer 140, a n-type contact electrode 180 formed on the exposed surface 150 of n-type semiconductor layer 120, a hydrogen-adsorbing layer 170 formed on the p-type cladding layer 160, and a metal contact layer 190 formed on the surface of the hydrogen-adsorbing layer.

First, a substrate 100 of, for example, sapphire is provided. The material of substrate 100 can also be spinnel, SiC, or GaAs. A buffer layer 110 of AlN, GaN, or AlGaN can be formed selectively on the substrate 100.

Second, a n-type GaN epitaxial layer 120 is formed on the buffer layer 110 by molecular beam epitaxy (MBE) process or metal-organic chemical vapor deposition (MOCVD) process.

Then an active layer 140 is formed on the n-type GaN epitaxial layer 120. The active layer 140 is of, for example, Indium compound (such as InGaN) or AlGaAs used in double hetero-structure LED, and other dopants such as Tl, or compounds such as CdSi, CdTe, ZnSi, ZnTe can be also added in to adjust the band gap of the active layer 140 and switch the wavelength of emitted light.

Then, a p-type GaN epitaxial layer 160 is formed by MBE or MOCVD process. The active layer 140 and the p-type GaN epitaxial payer 160 are then patterned by etching to expose the part of the surface 150 of the n-type GaN epitaxial layer 120. Then a hydrogen-adsorbing layer 170 is deposited on the surface of the p-type GaN epitaxial layer 160 by, for example, evaporation. A n-type contact electrode 180 is then formed on the surface 150. The material of the hydrogen-adsorbing layer 170 is Ta, V, Zr, Th, Ti, Pd, PdAg, Mg2Ni, NiTi, FeTi or LaNi5. Then a metal contact layer 180 of, for example, Au is formed on the hydrogen-adsorbing layer 170 by, for example, sputtering.

While the invention has been described by way of example and in terms of the preferred embodiments, it is to be understood that the invention is not limited to the disclosed embodiments. On the contrary, it is intended to cover various modifications and similar arrangements as would be apparent to those skilled in the art. Thus, the scope of the appended claims should be accorded the broadest interpretation so as to encompass all such modifications and similar arrangements.

What is claimed is:

1. A light-emitting diode, comprising:
a substrate;
a n-type semiconductor layer formed on the substrate;
an active layer formed on the n-type semiconductor layer;
a p-type cladding layer formed on the active layer; and
a hydrogen-adsorbing layer formed on the p-type cladding layer.

2. A light-emitting diode as claimed in claim 1, wherein the hydrogen-adsorbing layer is Ta, V, Zr, Th, Ti, Pd, PdAg, Mg2Ni, NiTi, FeTi, or LaNi5.

3. A light-emitting diode as claimed in claim 1, wherein the thickness of the hydrogen-adsorbing layer is between 1˜1000 Å.

4. A light-emitting diode as claimed in claim 1, further comprising a metal conducting layer formed on the hydrogen-adsorbing layer to serve as an electrode.

5. A light-emitting diode as claimed in claim 1, wherein the substrate is sapphire, SiC, spinnel or GaAs.

6. A light-emitting diode as claimed in claim 1, wherein the p-type cladding layer is p-type GaN.

7. A method for fabricating a light-emitting diode, comprising:
providing a substrate;
forming a n-type semiconductor layer on the substrate;
forming an active layer on the n-type semiconductor layer;
forming a p-type cladding layer on the active layer; and
forming a hydrogen-adsorbing layer on the p-type cladding layer.

8. A method for fabricating a light-emitting diode as claimed in claim 7, wherein the hydrogen-adsorbing layer is Ta, V, Zr, Th, Ti, Pd, PdAg, Mg₂Ni, NiTi, FeTi, or LaNi₅.

9. A method for fabricating a light-emitting diode as claimed in claim 7, wherein the thickness of the hydrogen-adsorbing layer is between 1˜1000 Å.

10. A method for fabricating a light-emitting diode as claimed in claim 7, further comprising forming a metal conducting layer on the hydrogen-adsorbing layer to serve as an electrode.

11. A method for fabricating a light-emitting diode as claimed in claim 7, wherein the substrate is sapphire, SiC, spinnel or GaAs.

12. A method for fabricating a light-emitting diode as claimed in claim 7, wherein the p-type cladding layer is p-type GaN.
